(19) United States
(12) Patent Application Publication
(10) Pub. No.: US 2011/0175113 A1
(43) Pub. Date: Jul. 21, 2011

(54) SEMICONDUCTOR LIGHT EMITTING DEVICE

(75) Inventors: Duk-Kyu BAE, Gyeonggi-Do (KR); Hwan-Kuk YUH, Gyeonggi-do (KR)

(73) Assignee: THELEDS CO., LTD., Gyeonggi-Do (KR)

(21) Appl. No.: 13/005,661

(22) Filed: Jan. 13, 2011

(30) Foreign Application Priority Data
Jan. 15, 2010 (KR) 10-2010-0003798

(51) Int. Cl. H01L 33/00

(52) U.S. Cl. 257/79; 257/E33.001

(57) ABSTRACT

Provided is a semiconductor light emitting device having an improved electrode structure for uniform current density and high brightness. According to the present invention, an light emitting device can have an electrode structure configured to spread a current uniformly and efficiently throughout the entire area of the light emitting device. Therefore, current density distribution can be more uniform in the light emitting device. End parts of second conductive type auxiliary electrodes are gradually shortened in length in a direction away from a first conductive type electrode pad so that a current flowing around the first conductive type electrode can be uniform to increase optical conversion efficiency and lower a driving voltage.

### CROSS-REFERENCE TO RELATED APPLICATION

This application claims priority to Korean Patent Application No. 2010-003798 filed on Jan. 15, 2010 and all the benefits accruing therefrom under 35 U.S.C. §119, the contents of which are incorporated by reference in their entirety.

### BACKGROUND

The present disclosure relates to a semiconductor light emitting device, and more particularly, to a semiconductor light emitting device having an improved electrode structure for uniform current density distribution.

Semiconductor light emitting devices such as light emitting diodes (LEDs) and laser diodes (LDs) are solid electronic devices for converting electricity into light. Such a semiconductor light emitting device includes a semiconductor-material active layer disposed between a p-type semiconductor layer and an n-type semiconductor layer. If a current is applied between ends of the p-type semiconductor layer and the n-type semiconductor layer, electrons and holes are injected into the semiconductor-material active layer from the n-type and p-type semiconductor layers. Then, light is generated while the injected electrons and holes are recombined at the semiconductor-material active layer

Generally, a semiconductor light emitting device formed of a nitride-based group III-V semiconductor compound having a compositional formula of AlₓIn_{y}Ga_{(1-x-y)}N (0≦x≦1, 0≦y≦1, 0≦x+y≦1) is capable of emitting short-wavelength light (from ultraviolet to green), particularly, blue light. In the case of a semiconductor light emitting device formed of a nitride-based semiconductor compound, since an insulating substrate such as a sapphire substrate or a silicon carbide (SiC) substrate is used to satisfy lattice matching conditions for crystal growth, a driving current is applied through two electrodes connected to a p-type semiconductor layer and an n-type semiconductor layer and arranged almost horizontally on the top surface of a light emitting structure (planar structure).

The brightness of such a nitride-based semiconductor light emitting device having a planar structure is required to be high so that the nitride-based semiconductor light emitting device can be used as an illumination source. For this, it is necessary to improve light emitting efficiency by uniformly diffusing a current. However, as compared with a nitride-based semiconductor light emitting device having a vertical structure in which two electrodes are respectively disposed on top and bottom surfaces of a light emitting structure, the nitride-based semiconductor light emitting device having a planar structure has a relatively low light emitting efficiency because current is not uniformly distributed in a light emitting region.

FIG. 1 is a sectional view illustrating a nitride-based semiconductor light emitting device 1 of the related art. In the light emitting device 1, an n-type semiconductor layer 3, and active layer 4, a p-type semiconductor layer 5, a transparent electrode 6 are stacked on an insulating sapphire substrate 2. Parts of the active layer 4, the p-type semiconductor layer 5, and the transparent electrode 6 are mesa-etched to expose the n-type semiconductor layer 3, and an n-type electrode 11 is formed on the exposed part of the n-type semiconductor layer 3. A p-type electrode 15 is formed on the transparent electrode 6. If a current is applied between the p-type electrode 15 and the n-type electrode 11, light is emitted as a current flows in the active layer 4. However, since the p-type electrode 15 and the n-type electrode 11 are generally remote, the current density of the light emitting device 1 is largely varied according to regions of the light emitting device 1. Uniform current density is necessary to improve light emitting efficiency and reduce a driving voltage.

FIG. 2 is a plane view illustrating an electrode structure of the related-art light emitting device 1 of FIG. 1. FIG. 1 is a sectional view taken along line I-I′ of FIG. 2.

Referring to FIG. 2, a p-type electrode pad 16 as a part of the p-type electrode 15 is formed at a side of the transparent electrode 6. The p-type electrode pad 16 may be wire-bonded in packaging process. An n-type electrode pad 12 is formed on the n-type semiconductor layer 3 at a side opposite to the p-type electrode pad 16. The n-type electrode pad 12 is a part of the n-type electrode 11 and may be wire-bonded in packaging process.

A p-type auxiliary electrode 17 formed on a side of the transparent electrode 6 is electrically connected to the p-type electrode pad 16 in a manner such that the p-type auxiliary electrode 17 extends from both sides of the p-type electrode pad 16. In addition, an n-type auxiliary electrode 13 formed in parallel with the p-type auxiliary electrode 17 is electrically connected to the n-type electrode pad 12 in a manner such that the n-type auxiliary electrode 13 extends from both sides of the n-type electrode pad 12.

In this structure, since a current applied to the p-type electrode pad 16 flows to the n-type electrode pad 12 in a horizontal direction, the path of the current is quite long. If the size of the light emitting device 1 increases, the length of the current path is also increased. This increases resistance, and thus a driving voltage is increased. In addition, current distribution is not uniform. If current distribution is not uniform, the intensity and uniformity of light emitted from the surface of the light emitting device 1 are reduced.

### SUMMARY

The present disclosure provides a semiconductor light emitting device having an electrode structure in which a current density can be uniformly distributed to improve optical output power characteristics, optical conversion efficiency, and brightness.

According to an exemplary embodiment, there is provided a semiconductor light emitting device including: a substrate; a first conductive type semiconductor layer, an active layer, and a second conductive type semiconductor layer that are sequentially disposed on the substrate, the second conductive type semiconductor layer having a type opposite to that of the first conductive type semiconductor layer; a second conductive type electrode including a second conductive type electrode pad and a second conductive type auxiliary electrode, the second conductive type electrode pad being disposed at one edge part on an upper side of the second conductive type semiconductor layer, the second conductive type auxiliary electrode being connected to the second conductive type electrode pad and being convex toward the one edge part; and a first conductive type electrode including a first conductive type electrode pad and a first conductive type auxiliary electrode, the first conductive type electrode pad being disposed at the other edge part opposite to the one edge part on the first conductive type semiconductor layer, the first conductive type auxiliary electrode being disposed along the other edge part in a manner such that the first conductive type auxiliary electrode extends from both sides of the first conductive type electrode pad, wherein tips of end parts of the second conductive type auxiliary electrode are placed on an imaginary line disposed between the second conductive type electrode pad and the first conductive type electrode pad and sloped toward the second conductive type electrode pad.

If a coordinate system having an x axis and an y axis perpendicular to the x axis is placed on a center of the semiconductor light emitting device, the second conductive type electrode pad is disposed in a third quadrant of the second conductive type semiconductor layer. The first conductive type electrode pad is disposed in a first quadrant of the first conductive type semiconductor layer. And the tips of the end parts of the second conductive type auxiliary electrode are placed on the imaginary line having a negative slope in the coordinate system.

The end parts of the second conductive type auxiliary electrode may be oriented toward the other edge part, particularly, with a slope of about 0 degrees to about 45 degrees and in a direction toward an opposite side of the first conductive type electrode pad. If the coordinate system having an x axis and an y axis perpendicular to the x axis is placed on a center of the semiconductor light emitting device, the second conductive type auxiliary electrode comprises at least two end parts oriented toward the first conductive type auxiliary electrode and having a zero or negative slope. At this time, the end parts of the second conductive type auxiliary electrode may have a linear shape or a curved shape. The second conductive type electrode pad may be connected to a convex part of the second conductive type auxiliary electrode. The end parts of the second conductive type auxiliary electrode may be parallel to each other.

Particularly, the semiconductor light emitting device may further include one or more second conductive type auxiliary electrodes, wherein end parts of neighboring second conductive type auxiliary electrodes may be connected to each other. The end parts of the second conductive type auxiliary electrodes may be spaced a predetermined distance from each other and be parallel with each other. The most convex part of the second conductive type auxiliary electrode may be inclined toward the first conductive type electrode pad along the one edge part. In other words, tangential lines at most convex parts of the second conductive type auxiliary electrodes have positive slopes in the coordinate system.

The second conductive type electrode pad may be connected to a convex part of one of the second conductive type auxiliary electrodes which is most distant from the first conductive type electrode pad. Positions where connection of the end parts of the neighboring second conductive type auxiliary electrodes are started may be arranged along the one edge part, and the neighboring second conductive type auxiliary electrodes may share a tip placed on the imaginary line. For example, the second conductive type auxiliary electrodes are at least three in number, and an imaginary line connecting points where connection of the end parts of the neighboring second conductive type auxiliary electrodes are started is parallel with the y axis in the coordinate system.

In the present disclosure, the semiconductor light emitting device may further include a conductive layer at least one of a position between the substrate and the first conductive type semiconductor layer and a position between the second conductive type semiconductor layer and the second conductive type electrode. If the conductive layer is disposed between the substrate and the first conductive type semiconductor layer, the conductive layer may be a buffer layer, and if the conductive layer is disposed between the second conductive type semiconductor layer and the second conductive type electrode, the conductive layer may be a transparent electrode.

In addition, the active layer may be disposed on the first conductive type semiconductor layer in a manner such that the active layer is recessed inward from edges of the first conductive type semiconductor layer. In this case, a current may flow smoothly from the first conductive type electrode pad to the second conductive type electrode through the first conductive type semiconductor layer.

### BRIEF DESCRIPTION OF THE DRAWINGS

Exemplary embodiments can be understood in more detail from the following description taken in conjunction with the accompanying drawings, in which:

FIG. 1 is a sectional view illustrating a semiconductor light emitting device of the related art, and

FIG. 2 is a plane view of the semiconductor light emitting device of the related;

FIG. 3 is plane view illustrating a semiconductor light emitting device according to an exemplary embodiment, and

FIG. 4 is a sectional view taken along line IV-IV′ of FIG. 3;

FIG. 5 is a plane view illustrating a light emitting device according to another exemplary embodiment;

FIG. 6 is a plane view illustrating a light emitting device according to another exemplary embodiment;

FIG. 7 is a plane view illustrating a light emitting device according to another exemplary embodiment;

FIG. 8 illustrates results of current density simulation performed on a semiconductor light emitting device of the related art;

FIG. 9 illustrates results of current density simulation performed on the semiconductor light emitting device of FIG. 5; and

FIG. 10 illustrates results of current density simulation performed on the semiconductor light emitting device of FIG. 7.

### DETAILED DESCRIPTION OF EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of layers and regions are exaggerated for clarity of illustration, and like reference numerals denote like elements. It will also be understood that when a layer (or film) is referred to as being ‘on’ another layer or substrate, it can be directly on the other layer or substrate, or intervening layers may also be present. In the following embodiments, it will be explained that a first conductive type is an n-type and a second conductive type is a p-type, and vice versa.

### Embodiment

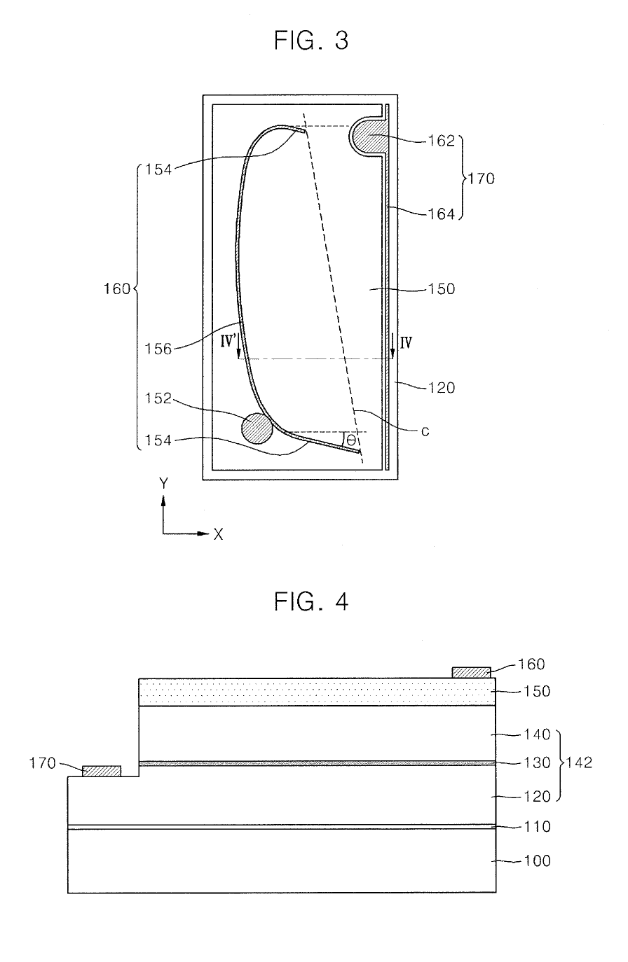

First, with reference to FIGS. 3 and 4, the structure of a semiconductor light emitting device will be described in detail according to an exemplary embodiment.

FIG. 3 is plane view illustrating a semiconductor light emitting device according to an exemplary embodiment, and FIG. 4 is a sectional view taken along line IV-IV′ of FIG. 3.

Referring to FIGS. 3 and 4, the semiconductor light emitting device of the current embodiment has a light emitting structure. The light emitting structure includes an epitaxial layer 142 including at least a n-type semiconductor layer 120, an active layer 130, and a p-type semiconductor layer 140 that are formed on a substrate 100. As shown in FIG. 3, the semiconductor light emitting device may further include a conductive layer at least one of a position between the substrate 100 and the n-type semiconductor layer 120 and a position between p-type semiconductor layer 140 and a p-type electrode 160. In the current embodiment, the conductive layer between the substrate 100 and the n-type semiconductor layer 120 is a buffer layer 110, and the conductive layer between the p-type semiconductor layer 140 and the p-type electrode 160 is a transparent electrode 150.

The substrate 100 is used to grow nitride semiconductor single crystal. For example, the substrate 100 may be made of a transparent material including sapphire. Instead of sapphire, zinc oxide (ZnO), gallium nitride (GaN), silicon carbide (SiC), or aluminum nitride (AlN) may be used.

Before the n-type semiconductor layer 120 is formed on the substrate 100, the buffer layer 110 is formed for lattice matching with the substrate 100. The buffer layer 110 may be formed of AlN/GaN. The buffer layer 110 is not an essential element of the light emitting device of the current embodiment, and thus the buffer layer 110 may be omitted according to the characteristics of the light emitting device and process conditions.

The n-type semiconductor layer 120, the active layer 130, and the p-type semiconductor layer 140 of the epitaxial layer 142 may be foamed of a semiconductor material having a compositional formula of In_{X}Al_{Y}Ga_{1-X-Y}N (0≦X, 0≦Y, X+Y≦1). Specifically, the n-type semiconductor layer 120 may be formed of GaN or GaN/AlGaN doped with an n-type dopant. Examples of the n-type dopant include Si, Ge, and Sn. For example, Si may be mostly used as the n-type dopant. The p-type semiconductor layer 140 may be formed of GaN or GaN/AlGaN doped with a p-type dopant. Examples of the p-type dopant include Mg, Zn, and Be. For example, Mg may be mostly used as the n-type dopant. The active layer 130 generates and emits light. Usually, the active layer 130 has a multi-quantum well structure constituted by an InGaN well layer and a GaN barrier layer. The active layer 130 may have a single quantum well structure or a double hetero structure. The buffer layer 110, the n-type semiconductor layer 120, the active layer 130, and the p-type semiconductor layer 140 are formed through a deposition process such as a metal organic chemical vapor deposition (MOCVD) process, a molecular beam epitaxy (MBE) process, and a hydride vapor phase epitaxy (HVPE) process.

The transparent electrode 150 may be formed of a conductive metal oxide. Alternatively, the transparent electrode 150 may be formed of a thin metal film having a higher conductivity and low contact resistance if the transparence of the thin metal film is high with reference to the wavelength of light emitted from the light emitting device. The transparent electrode 150 is not an essential element of the light emitting device of the current embodiment, and thus the transparent electrode 150 may be omitted according to the characteristics of the light emitting device and process conditions.

The topside of the n-type semiconductor layer 120 is partially exposed by removing a part of the epitaxial layer 142, for example, parts of the active layer 130 and the p-type semiconductor layer 140, and a part of the transparent electrode 150 through a mesa etching process. At this time, edges of the active layer 130 may be recessed from edges of the n-type semiconductor layer 120, so as to uniformly spread a current in the entire region of the active layer 130, that is, the entire region of a light emitting area when the nitride-based semiconductor light emitting device is operated. Edges of the transparent electrode 150 may also be recessed from edges of the p-type semiconductor layer 140.

As shown in FIG. 3, the light emitting device may be about 500 μm in x-axis length and about 1000 μm in y-axis length. That is, the light emitting device may have a 500 μm×1000 μm rectangular shape. The p-type electrode 160 includes a p-type electrode pad 152 which is a wire bonding region. The p-type electrode pad 152 is formed on one edge part of the transparent electrode 150. For example, the p-type electrode pad 152 may be formed at a position where the p-type semiconductor layer 140 is exposed by etching a part of the transparent electrode 150 in a long axis (y) direction, or the p-type electrode pad 152 may be formed on the transparent electrode 150. In any case, the p-type electrode pad 152 is formed at one edge part of the topside of the p-type semiconductor layer 140 disposed under the transparent electrode 150. The p-type electrode pad 152 may be fainted at one edge part of the light emitting device so that the light emitting area of the light emitting device can be less reduced. In the current embodiment, if possible, the p-type electrode pad 152 is formed at a position close to a corner of the light emitting device.

Parts of the active layer 130, the p-type semiconductor layer 140, and the transparent electrode 150 are mesa-etched to expose the n-type semiconductor layer 120, and an n-type electrode 170 is formed on the exposed part of the n-type semiconductor layer 120. The n-type electrode 170 includes an n-type electrode pad 162 formed on the n-type semiconductor layer 120 at the other edge part opposite to the p-type electrode pad 152. If possible, the n-type electrode pad 162 is faulted at a position close to a corner of the light emitting device.

The p-type electrode 160 is connected to the p-type electrode pad 152. The p-type electrode 160 includes a p-type auxiliary electrode 156 which is convex toward the one edge part at which the p-type electrode pad 152 is disposed. In the current embodiment, the p-type electrode pad 152 is connected to a convex part of the p-type auxiliary electrode 156. The n-type electrode 170 includes an n-type auxiliary electrode 164 formed along the other edge part in a manner such that the n-type auxiliary electrode 164 extends from both sides of the n-type electrode pad 162.

End parts 154 of the p-type auxiliary electrode 156 are placed on an imaginary line (c), which is drawn between the p-type electrode pad 152 and the n-type electrode pad 162 at an inclined angle toward the p-type electrode pad 152, in a manner such that the end parts 154 of the p-type auxiliary electrode 156 are located at other edge parts than the above-described edge parts of the p-type semiconductor layer 140. That is, the end parts 154 of the p-type auxiliary electrode 156 are located at edge parts parallel with the short axis (x) of the rectangular shape. Thus, the end part 154 of the p-type auxiliary electrode 156 close to the n-type electrode pad 162 is not long. The other end part 154 of the p-type auxiliary electrode 156 is disposed at a side opposite to the n-type electrode pad 162 and oriented toward the other edge part at an angle θ greater than about 0 degrees but smaller than or equal to about 45 degrees. The end parts 154 of the p-type auxiliary electrode 156 are gradually shortened in length in a direction away from the n-type electrode pad 162.

The part of the p-type auxiliary electrode 156 which is convex toward the one edge part may have an arch shape. For example, the most convex part of the p-type auxiliary electrode 156 may be inclined along the one edge part toward the n-type electrode pad 162.

The p-type auxiliary electrode 156 may have a curved shape or a partially linear shape as long as the p-type auxiliary electrode 156 is convex toward the one edge part. That is, the end parts 154 of the p-type auxiliary electrode 156 may have a curved shape or a linear shape as shown in FIG. 3. For example, the end parts 154 of the p-type auxiliary electrode 156 may be parallel with each other for effective current spreading. In this case, a current can be uniformly spread throughout the entire light emitting area.

The p-type electrode pad 152 and the n-type electrode pad 162 may have the same shape and size, and the p-type auxiliary electrode 156 and the n-type auxiliary electrode 164 may have the same line width. A large line width is advantageous because effective current spreading is possible but is disadvantageous due to undesired light absorption or blocking. Similarly, as the distance between the p-type auxiliary electrode 156 and the n-type auxiliary electrode 164 is decreased, light absorption or blocking increases although current spreading may increase. Therefore, it may be necessary to keep a proper line width and a line distance.

In actual manufacturing processes, after the buffer layer 110, the epitaxial layer 142, and the transparent electrode 150 are grown or formed on the substrate 100, the p-type electrode 160 is formed by depositing a metal on the transparent electrode 150 and stripping the metal by a lift-off method using photoresist. Thereafter, the active layer 130, the p-type semiconductor layer 140, and the transparent electrode 150 are etched to form a groove having a shape corresponding to the n-type electrode 170, and then the n-type electrode 170 is formed. If the thicknesses of the p-type electrode 160 and the n-type electrode 170 are large, resistance can be reduced but costs increase. Thus, it may be necessary to select a proper thickness.

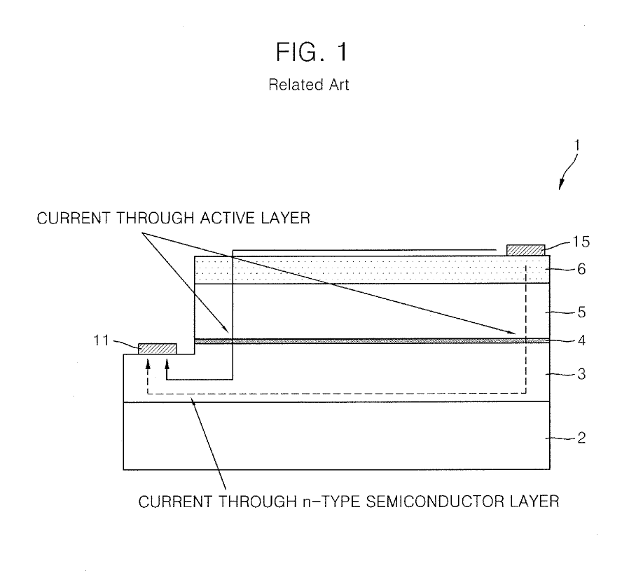

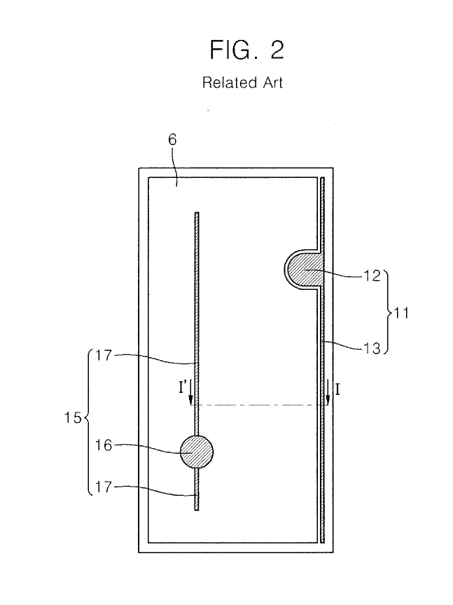

In the case of the light emitting device 1 of the related art explained with reference to FIGS. 1 and 2, the distance between the n-type electrode 11 and the p-type electrode 15 is long. However, according to the current embodiment, the distance between the n-type electrode 170 and the p-type electrode 160 is close owing to the p-type auxiliary electrode 156. Thus, current density can be more uniform.

Owning to the p-type electrode 160, a current can flow uniformly throughout the active layer 130 from the p-type electrode 160 to the n-type electrode 170, and thus electrons and holes can be uniformly injected into the active layer 130. Therefore, as the electrons and holes are recombined in the active layer 130, light can be emitted more uniformly and efficiently.

According to the embodiment, an unnecessary electrode part can be removed to increase an actual light emitting area and light emitting efficiency. In addition, current spreading can be facilitated to reduce a driving voltage and increase light emitting efficiency.

The output power and flux of light of a light emitting diode (LED) can be increased by increasing the size of LED. The electrode structure described in the current embodiment has improved current injection and spreading characteristics and can be applied to an LED larger than a LED of the related art. That is, a current can be uniformly distributed throughout the active layer 130. That is, electrons and holes can be uniformly injected to the active layer 130 for generating light in the active layer 130.

### Another Embodiment

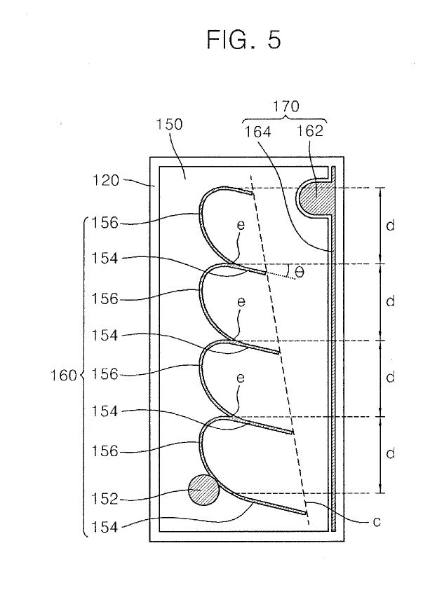

Next, with reference to FIG. 5, the structure of a semiconductor light emitting device will be described in detail according to another exemplary embodiment. In descriptions of the current embodiment, descriptions of the same elements as those of the previous embodiment will not be repeated. Descriptions will be given on different elements.

FIG. 5 is a plane view illustrating a light emitting device according to another exemplary embodiment.

Referring to FIG. 5, more p-type auxiliary electrodes 156 are provided as compared with the embodiment explained with reference to FIG. 3. In the current embodiment, four p-type auxiliary electrodes 156 are formed along a line (c), end parts 154 of neighboring p-type auxiliary electrodes 156 are connected to each other. In the current embodiment, approximately U-shaped paths which overlap each other are formed by the p-type auxiliary electrodes 156.

Neighboring end parts 154 of the p-type auxiliary electrodes 156 are arranged at regular intervals (d) in parallel with each other for uniform spreading of current. The most convex parts of the p-type auxiliary electrodes 156 are inclined toward an n-type electrode pad 162 along one edge part. A p-type electrode pad 152 is connected to a convex part of one of the p-type auxiliary electrodes 156 which is most distant from the n-type electrode pad 162. Positions (e) where connection of the neighboring end parts 154 of the p-type auxiliary electrodes 156 are started are arranged along the one edge part.

As the number of the p-type auxiliary electrodes 156 increases, current spreading characteristics can be improved. However, light absorption and blocking increase. Therefore, it may be necessary to use a proper number of p-type auxiliary electrodes 156.

### Another Embodiment

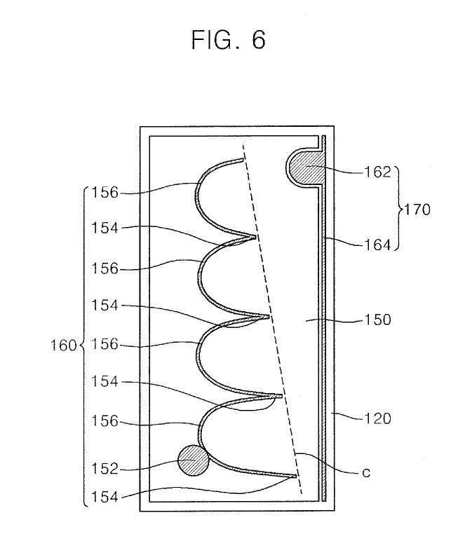

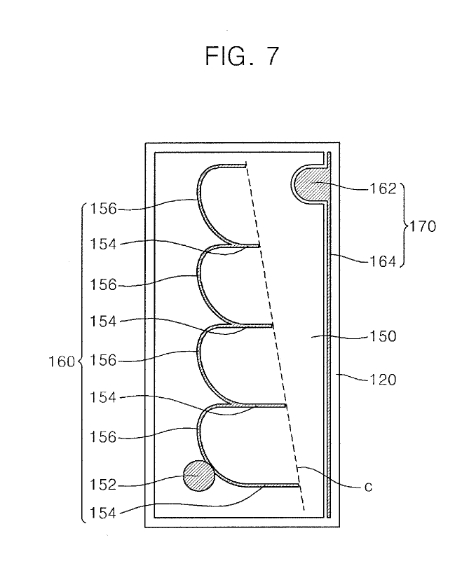

Next, with reference to FIG. 6, the structure of a semiconductor light emitting device will be described in detail according to another exemplary embodiment. In descriptions of the current embodiment, descriptions of the same elements as those of the previous embodiment shown in FIG. 5 will not be repeated. Descriptions will be given on different elements.

FIG. 6 is a plane view illustrating a light emitting device according to another exemplary embodiment. In the embodiment explained with reference to FIG. 5, the end parts 154 of neighboring p-type auxiliary electrodes 156 are connected to each other by a predetermined length. However, in the current embodiment shown in FIG. 6, end parts 154 of neighboring p-type auxiliary electrodes 156 are connected to each other in a manner such that only tips of the end parts 154 placed along a line (c) are commonly connected.

### Another Embodiment

Next, with reference to FIG. 7, the structure of a semiconductor light emitting device will be described in detail according to another exemplary embodiment. In descriptions of the current embodiment, descriptions of the same elements as those of the previous embodiment shown in FIG. 5 will not be repeated. Descriptions will be given on different elements.

FIG. 7 is a plane view illustrating a light emitting device according to another exemplary embodiment. Referring to FIG. 7, the light emitting device of the current embodiment has the same structure as the light emitting device of the previous embodiment explained with reference to FIG. 5, except that end parts 154 of p-type auxiliary electrodes 156 are not inclined (angle=about 0 degree) and are perpendicular to an n-type auxiliary electrode 164.

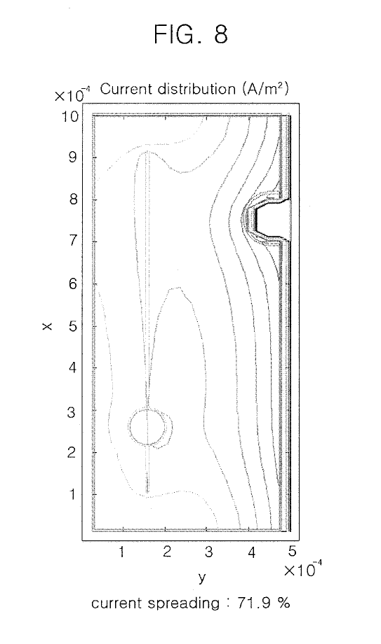

FIGS. 8 through 10 illustrates results of current density simulations performed on a light emitting device of the related art, the light emitting device of the embodiment of FIG. 5, and the light emitting device of the embodiment of FIG. 7.

FIG. 8 shows a current distribution of the related-art light emitting device 1 explained with reference to FIGS. 1 and 2. Current spreading is about 71.9% and non-uniform. This results in poor lighting.

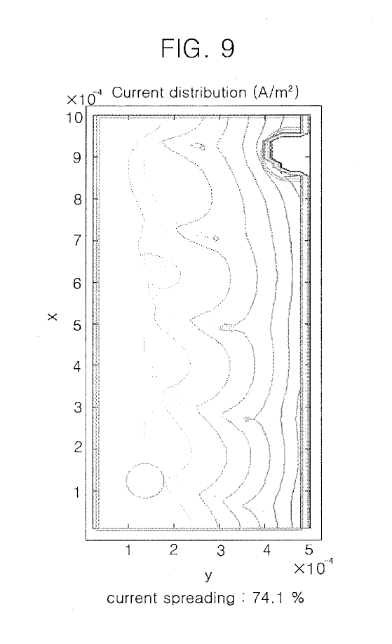

FIG. 9 illustrates a current distribution of the semiconductor light emitting device of the embodiment explained with reference to FIG. 5. Since the distance between the p-type auxiliary electrodes 156 and the n-type auxiliary electrode 164 is reduced and varied, current uniformity is improved. Current spreading is about 74.1%, greater than that shown in FIG. 8.

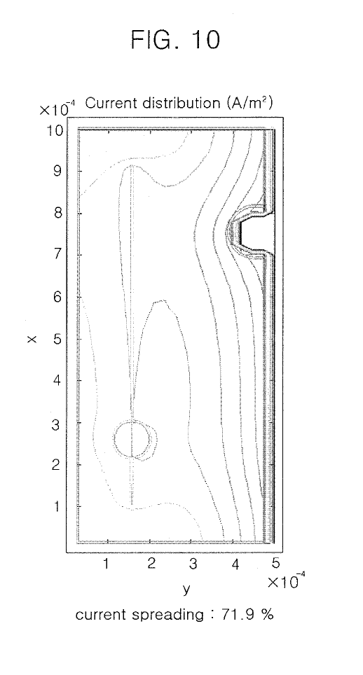

FIG. 10 illustrates a current distribution of the semiconductor light emitting device of the embodiment explained with reference to FIG. 7. Since the distance between the p-type auxiliary electrodes 156 and the n-type auxiliary electrode 164 is reduced and varied, current uniformity is improved. Current spreading is about 73.4%, less than that shown in FIG. 9 but greater than that shown in FIG. 8.

Light emitting device were actually made, and the driving voltages and optical output powers of the light emitting devices were measured.

The driving voltage, optical output power, and optical conversion efficiency (optical output power/input current) of a light emitting device 1 of the related art were about 3.53 V, about 98 mW, and about 27.8%, respectively. The driving voltage, optical output power, and optical conversion efficiency of a light emitting device of the embodiment of FIG. 5 were about 3.45 V, about 106.72 mW, and about 30.96%, respectively. The driving voltage, optical output power, and optical conversion efficiency of a light emitting device of the embodiment of FIG. 7 were about 3.49 V, about 106.26 mW, and about 30.48%, respectively. That is, according to the embodiments of the present disclosure, the driving voltage of a light emitting device can be reduced but the optical output power of the light emitting device can be increased. That is, the optical conversion efficiency of the light emitting device can be increased as compared with that of a light emitting device of the related art.

In the above-described embodiments, rectangular light emitting devices are explained. However, the present invention is not limited thereto. For example, the present invention can be applied to square light emitting devices such as a 750 μm×750 μm light emitting device and a 1000 μm×1000 μm light emitting device. In this case, the shapes and lengths of p-type and n-type electrodes may be properly adjusted.

According to the present disclosure, the light emitting device can have an electrode structure configured to spread a current uniformly and efficiently throughout the entire area of the light emitting device. Therefore, current density distribution can be more uniform in the light emitting device. End parts of second conductive type auxiliary electrodes are gradually shortened in length in a direction away from a first conductive type electrode pad so that a current flowing around the first conductive type electrode can be uniform to increase optical conversion efficiency and lower a driving voltage.

In addition, unnecessary electrodes can be minimized to increase the actual light emitting area and optical conversion efficiency.

Although the semiconductor light emitting device has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A semiconductor light emitting device comprising:
a substrate; and
a first conductive type semiconductor layer, an active layer, and a second conductive type semiconductor layer that are sequentially disposed on the substrate, the second conductive type semiconductor layer having a type opposite to that of the first conductive type semiconductor layer,
wherein if a coordinate system having an x axis and an y axis perpendicular to the x axis is placed on a center of the semiconductor light emitting device, the semiconductor light emitting device further comprises:
a second conductive type electrode comprising a second conductive type electrode pad and a second conductive type auxiliary electrode, the second conductive type electrode pad being disposed at one edge part along the y axis in a third quadrant of the second conductive type semiconductor layer, the second conductive type auxiliary electrode being connected to the second conductive type electrode pad and being convex toward the one edge part; and
a first conductive type electrode comprising a first conductive type electrode pad and a first conductive type auxiliary electrode, the first conductive type electrode pad being disposed at the other edge part opposite to the one edge part in a first quadrant of the first conductive type semiconductor layer, the first conductive type auxiliary electrode being disposed along the other edge part in a manner such that the first conductive type auxiliary electrode extends from both sides of the first conductive type electrode pad,
wherein the second conductive type auxiliary electrode comprises at least two end parts oriented toward the first conductive type auxiliary electrode and having a zero or negative slope, and tips of the end parts of the second conductive type auxiliary electrode are placed on an imaginary line having a negative slope in the coordinate system.

2. The semiconductor light emitting device of claim 1, wherein the end parts of the second conductive type auxiliary electrode have a slop of about −1 to about zero.

3. The semiconductor light emitting device of claim 1, wherein the end parts of the second conductive type auxiliary electrode have a linear shape or a curved shape.

4. The semiconductor light emitting device of claim 1, wherein the second conductive type electrode pad is connected to a convex part of the second conductive type auxiliary electrode.

5. The semiconductor light emitting device of claim 1, wherein the end parts of the second conductive type auxiliary electrode are parallel to each other.

6. The semiconductor light emitting device of claim 1, further comprising one or more second conductive type auxiliary electrodes, wherein the second conductive type auxiliary electrodes are arranged along the y axis, and end parts of neighboring second conductive type auxiliary electrodes are connected to each other.

7. The semiconductor light emitting device of claim 6, wherein the end parts of the second conductive type auxiliary electrodes are spaced a predetermined distance from each other.

8. The semiconductor light emitting device of claim 6, wherein the end parts of the second conductive type auxiliary electrodes are parallel with each other.

9. The semiconductor light emitting device of claim 6, wherein tangential lines at most convex parts of the second conductive type auxiliary electrodes have positive slopes.

10. The semiconductor light emitting device of claim 6, wherein the second conductive type electrode pad is connected to a convex part of one of the second conductive type auxiliary electrodes which is most distant from the first conductive type electrode pad.

11. The semiconductor light emitting device of claim 6, wherein the second conductive type auxiliary electrodes are at least three in number, and an imaginary line connecting points where connection of the end parts of the neighboring second conductive type auxiliary electrodes are started is parallel with the y axis.

12. The semiconductor light emitting device of claim 6, wherein the neighboring second conductive type auxiliary electrodes share a tip placed on the imaginary line.

13. The semiconductor light emitting device of claim 2, wherein the end parts of the second conductive type auxiliary electrode have a linear shape or a curved shape.

14. The semiconductor light emitting device of claim 2, wherein the second conductive type electrode pad is connected to a convex part of the second conductive type auxiliary electrode.

15. The semiconductor light emitting device of claim 2, wherein the end parts of the second conductive type auxiliary electrode are parallel to each other.

16. The semiconductor light emitting device of claim 2, further comprising one or more second conductive type auxiliary electrodes, wherein the second conductive type auxiliary electrodes are arranged along the y axis, and end parts of neighboring second conductive type auxiliary electrodes are connected to each other.

17. The semiconductor light emitting device of claim 16, wherein the end parts of the second conductive type auxiliary electrodes are parallel with each other.

18. The semiconductor light emitting device of claim 16, wherein tangential lines at most convex parts of the second conductive type auxiliary electrodes have positive slopes.

19. The semiconductor light emitting device of claim 16, wherein the second conductive type auxiliary electrodes are at least three in number, and an imaginary line connecting points where connection of the end parts of the neighboring second conductive type auxiliary electrodes are started is parallel with the y axis.

20. The semiconductor light emitting device of claim 16, wherein the neighboring second conductive type auxiliary electrodes share a tip placed on the imaginary line.
